(19) United States
(12) Patent Application Publication
(10) Pub. No.: US 2015/0059852 A1
(43) Pub. Date: Mar. 5, 2015

(54) FLEXIBLE PHOTOVOLTAIC APPARATUS

(71) Applicant: Fuchi Textile Co., Ltd., Keelung City (TW)

(72) Inventors: Ming-Teng CHEN, Keelung City (TW); Chun-An WU, Keelung City (TW); Zheng-Hao OU, Taichung City (TW)

(21) Appl. No.: 14/471,563

(22) Filed: Aug. 28, 2014

(30) Foreign Application Priority Data
Aug. 29, 2013 (TW) 102216203

(51) Int. Cl. H01L 31/0392; H01L 31/048; H01L 31/0445; H01G 9/20

(52) U.S. Cl. CPC H01L 31/03926; H01G 9/2095; H01L 31/03928; H01L 31/0481; H01L 31/0445
USPC 136/259

(57) ABSTRACT

The invention discloses a flexible photovoltaic apparatus including a composite fabric structure, a thin film photovoltaic device and a protection layer. The thin film photovoltaic device is bonded on an upper surface of the composite fabric structure. The protection layer is transparent, and is bonded on the thin film photovoltaic device and the upper surface of the composite fabric structure such that two terminals of the thin film photovoltaic device are exposed. A lower surface of the composite fabric structure serves as a decorative surface.

### CROSS-REFERENCE TO RELATED APPLICATION

This utility application claims priority to Taiwan Application Serial Number 102216203, filed Aug. 29, 2013, which is incorporated herein by reference.

### BACKGROUND OF THE INVENTION

1. Field of the Invention

The invention relates to a flexible photovoltaic apparatus, and in particular, to the flexible photovoltaic apparatus which can be easily designed and integrated into daily necessities and has high flexibility.

2. Description of the Prior Art

Current flexible photovoltaic apparatus includes an amorphous silicon or micro-crystalline silicon (μ-Si) thin film photovoltaic device sealed between two layers of polytetrafluoroethylene (PTFE). However, the light-incident face of current amorphous silicon or micro-crystalline thin film photovoltaic device exhibits dark blue or dark black, and the PTFE layers are transparent. Therefore, the appearance of the amorphous silicon or micro-crystalline thin film photovoltaic device is unsightly, and that limits applications of current flexible photovoltaic apparatus and makes it difficult to design and integrate current flexible photovoltaic apparatus into daily necessities.

In addition, there is a huge space to improve the flexibility of current flexible photovoltaic apparatus to expand applications of the flexible photovoltaic apparatus.

### SUMMARY OF THE INVENTION

Accordingly, one scope of the invention is to provide a flexible photovoltaic apparatus which can be easily designed and integrated into daily necessities and has high flexibility.

According to a preferred embodiment of the invention, a flexible photovoltaic apparatus includes a composite fabric structure, a thin film photovoltaic device and a protection layer. The thin film photovoltaic device is bonded on an upper surface of the composite fabric structure. The protection layer is transparent, and is bonded on the thin film photovoltaic device and the upper surface of the composite fabric structure such that two terminals of thin film photovoltaic device are exposed. The lower surface of the composite fabric structure serves as a decorative surface.

In one embodiment, composite fabric structure includes a base layer and a fabric layer. The base layer provides the upper surface. The fabric layer is bonded together with the base layer, and provides the lower surface.

In one embodiment, fabric layer can be a textile fabric layer, a natural leather layer or an artificial leather layer.

In one embodiment, the base layer can be formed of ethylene-tetra-fluoro-ethylene (ETFE), polytetrafluoroethylene (PTFE), polymethyl methacrylate (PMMA), thermoplastic polyurethane (TPU), ethylene-vinyl acetate (EVA), polyurethane (PU), polyethylene terephthalate (PET) or other commercial synthetic resin.

In one embodiment, the protection layer can be formed of PTFE, PMMA, EVA or other commercial synthetic resin.

In one embodiment, thin film photovoltaic device can be an amorphous silicon thin film photovoltaic device, a microcrystalline silicon thin film photovoltaic device, a CdS thin film photovoltaic device, a CdTe thin film photovoltaic device, a CuInSe₂ thin film photovoltaic device, a Cu(In,Ga)Se₂ thin film photovoltaic device, a dye-sensitized thin film photovoltaic device, etc.

Distinguishable from the prior art, the flexible photovoltaic apparatus of the invention includes the fabric layer providing decorative effect which makes it easy to design and integrate the flexible photovoltaic apparatus of the invention into daily necessities. Moreover, the flexible photovoltaic apparatus of the invention has high flexibility.

The advantage and spirit of the invention may be understood by the following recitations together with the appended drawings.

### BRIEF DESCRIPTION OF THE APPENDED DRAWINGS

FIG. 1 is a schematic diagram illustrating the top view of a flexible photovoltaic apparatus according to the first preferred embodiment of the invention.

FIG. 2 is a sectional view of the flexible photovoltaic apparatus shown in FIG. 1 along line A-A.

FIG. 3 is a sectional view of a flexible photovoltaic apparatus according to the second preferred embodiment of the invention.

FIG. 4 is a sectional view of a flexible photovoltaic apparatus according to the third preferred embodiment of the invention.

### DETAILED DESCRIPTION OF THE INVENTION

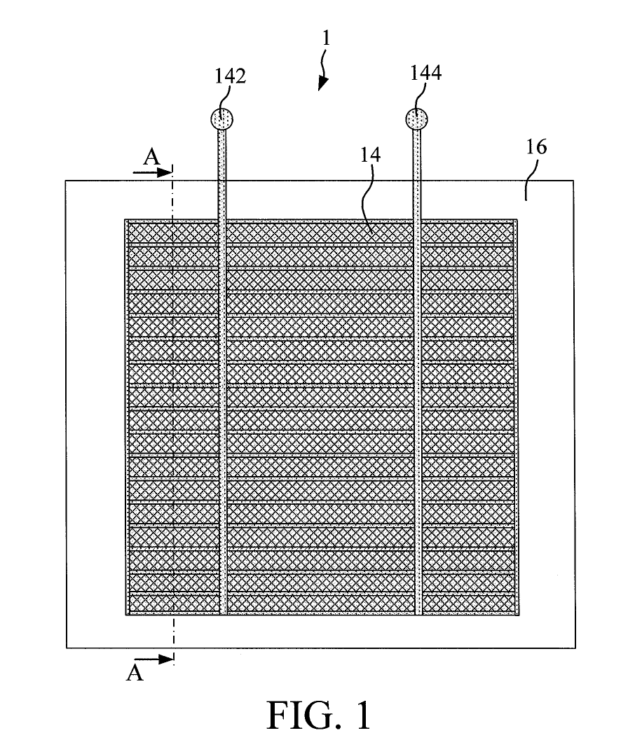

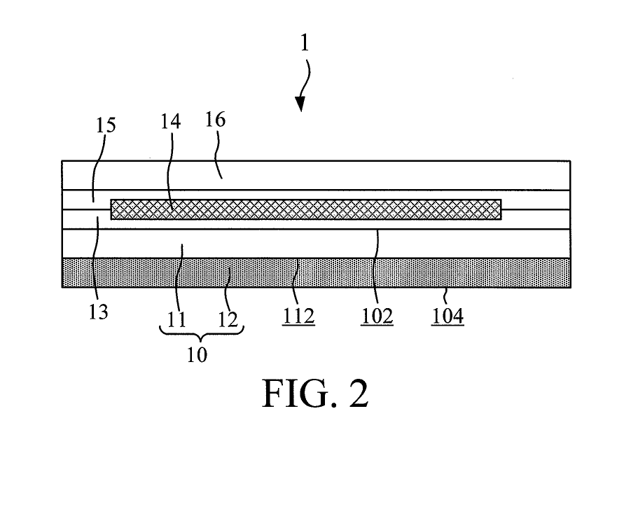

Referring to FIGS. 1 and 2, FIG. 1 is a schematic diagram illustrating the top view of a flexible photovoltaic apparatus 1 according to the first preferred embodiment of the invention. FIG. 2 is a sectional view of the flexible photovoltaic apparatus 1 shown in FIG. 1 along line A-A.

As shown in FIG. 1 and FIG. 2, the flexible photovoltaic apparatus 1 according to the first preferred embodiment of the invention includes a composite fabric structure 10, a thin film photovoltaic device 14 and a protection layer 16.

The thin film photovoltaic device 14 is bonded on the upper surface 102 of the composite fabric structure 10. The protection layer 16 is transparent and bonded on the thin film photovoltaic device 14 and the upper surface 102 of the composite fabric structure 10 such that two terminals (142 and 144) of the thin film photovoltaic device 14 are exposed, as shown in FIG. 1. The exposed two terminals (142 and 144) provide electrical connection in series with other thin film photovoltaic device 14, or provide electrical connection with an external circuit. In particular, the lower surface 104 of the composite fabric structure 10 serves as a decorative surface.

In one embodiment, the composite fabric structure 10 includes a base layer 11 and a fabric layer 12. The base layer 11 provides the upper surface 102. The fabric layer 12 is bonded together with the base layer 11. As shown in FIG. 1, the fabric layer 12 is bonded on the lower surface 112 of the base layer 11. The fabric layer 12 also provides the lower surface 104 (decorative surface 104).

In one embodiment, the fabric layer 12 can be a textile fabric layer, a natural leather layer or an artificial leather layer. The textile fabric layer as the fabric layer 12 can be all kinds of textile fabrics, for example, woven fabric, warp knitting fabric, circular knitted fabric, velvet, non-woven fabric, etc. The decorative surface 104 of the fabric layer 12 can be applied by post-treatments, for example, printing, gluing, shaping, pollution preventing, fire resisting, fluffing, sanding, shearing, calendering, embossing, laminating, or other treatment.

As shown in FIG. 2, the flexible photovoltaic apparatus 1 of the invention also includes a sealing layer 13 (e.g., an EVA layer) and a sealing layer 15 (e.g., an EVA layer). The sealing layer 13 is boned between the base layer 11 and the thin film photovoltaic device 14. The sealing layer 15 is bonded between the protection layer 16 and the thin film photovoltaic device 14. In one embodiment, base layer 11, the sealing layer 13, the thin film photovoltaic device 14, the sealing layer 15 and the protection layer 16 are bonded together by hot press. The sealing layer 13 and the sealing layer 15 seal the thin film photovoltaic device 14.

In one embodiment, the base layer 11 can be formed of ETFE, PTFE, PMMA, TPU, EVA, PU, PET or other commercial synthetic resin. The base layer 11 must meet the requirements of various weathering properties to protect the thin film photovoltaic device 14.

In one embodiment, thin film photovoltaic device 14 can be an amorphous silicon thin film photovoltaic device, a microcrystalline silicon (μ-Si) thin film photovoltaic device, a CdS thin film photovoltaic device, a CdTe thin film photovoltaic device, a CuInSe₂ (CIS) thin film photovoltaic device, a Cu(In,Ga)Se₂ (CIGS) thin film photovoltaic device, a dye-sensitized thin film photovoltaic device, etc.

In one embodiment, the protection layer 16 can be formed of PTFE, PMMA, EVA or other commercial synthetic resin. The protection layer 16 must meet the requirements of water vapor barrier, electrical insulation, dimensional stability, moist heat aging resistance, anti-ultraviolet, etc.

In one embodiment, the flexible photovoltaic apparatus 1 according to the first preferred embodiment of the invention has a thickness in a range of about from 0.05 mm to 5 mm. The flexible photovoltaic apparatus 1 according to the first preferred embodiment of the invention can be wound into a tubular article. The flexibility of the flexible photovoltaic apparatus 1 according to the first preferred embodiment of the invention is defined as a diameter of the tubular article which is about form 5 mm to 500 mm.

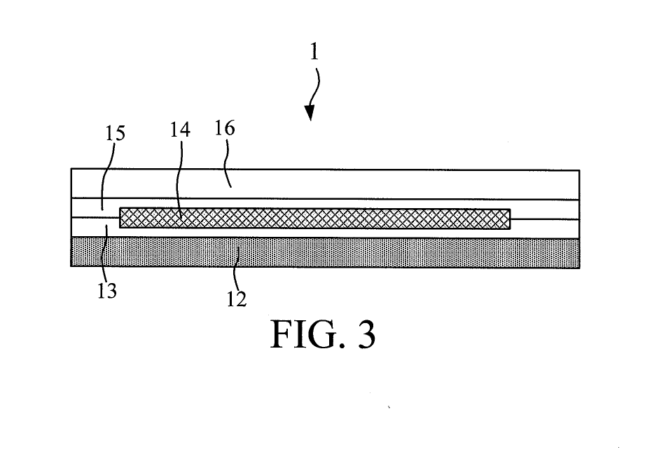

Referring to FIG. 3, FIG. 3 is a sectional view of a flexible photovoltaic apparatus 1 according to the second preferred embodiment of the invention. The components and devices in FIG. 3 identical to those shown in FIG. 2 are given the same numerical notations, and will be not described in detail herein. Hereinafter, only difference between the second preferred embodiment and the first preferred embodiment is described.

In the second preferred embodiment of the invention, the flexible photovoltaic apparatus 1 has no base layer 11, the fabric layer 12 is directly bonded on the sealing layer 13 (e.g., EVA layer). The fabric layer 12 provides the decorative surface.

Similarly, the flexible photovoltaic apparatus 1 according to the second preferred embodiment of the invention has a thickness in a range of about from 0.05 mm to 5 mm. The flexible photovoltaic apparatus 1 according to the second preferred embodiment of the invention can be wound into a tubular article. The flexibility of the flexible photovoltaic apparatus 1 according to the second preferred embodiment of the invention is defined as a diameter of the tubular article which is about form 5 mm to 500 mm.

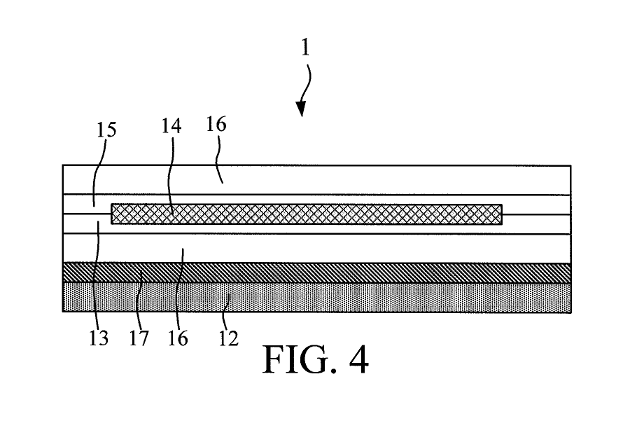

Referring to FIG. 4, FIG. 4 is a sectional view of a flexible photovoltaic apparatus 1 according to the third preferred embodiment of the invention. The components and devices in FIG. 4 identical to those shown in FIG. 2 are given the same numerical notations, and will be not described in detail herein. Hereinafter, only difference between the third preferred embodiment and the first preferred embodiment is described.

In the second preferred embodiment of the invention, the flexible photovoltaic apparatus 1 has no base layer 11, another protection layer 16 is directly bonded on the sealing layer 13 (e.g., EVA layer). An interface layer 17 glues the protection layer 16 and the fabric layer 12. The fabric layer 12 provides the decorative surface.

With above description of the flexible photovoltaic apparatus of the invention, it is clearly understood that the flexible photovoltaic apparatus of the invention provides decorative effect and has high flexibility. Therefore, the flexible photovoltaic apparatus of the invention can expand applications thereof, and can be easily designed and integrated into daily necessities.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A flexible photovoltaic apparatus, comprising:
a composite fabric structure, having an upper surface and a lower surface;
a thin film photovoltaic device, being bonded on the upper surface of the composite fabric structure and having two terminals; and
a protection layer, being transparent and being bonded on the thin film photovoltaic device and the upper surface of the composite fabric structure such that said two terminals of the thin film photovoltaic device are exposed, wherein the lower surface of the composite fabric structure serves as a decorative surface.

2. The flexible photovoltaic apparatus of claim 1, wherein the composite fabric structure comprises:
a base layer, providing the upper surface; and
a fabric layer, being bonded together with the base layer and providing the lower surface.

3. The flexible photovoltaic apparatus of claim 2, wherein the fabric layer is one selected from the group consisting of a textile layer, a natural leather layer and an artificial leather layer.

4. The flexible photovoltaic apparatus of claim 2, wherein the base layer is formed of ethylene-tetra-fluoro-ethylene (ETFE), polytetrafluoroethylene (PTFE), polymethyl methacrylate (PMMA), thermoplastic polyurethane (TPU), ethylene-vinyl acetate (EVA), polyurethane (PU) and polyethylene terephthalate (PET).

5. The flexible photovoltaic apparatus of claim 2, wherein the protection layer is formed of PTFE, PMMA, EVA and PET.

6. The flexible photovoltaic apparatus of claim 2, further comprising:
a first sealing layer, bonded between the thin film photovoltaic device and the protection layer; and
a second sealing layer, bonded between the thin film photovoltaic device and the base layer.

7. The flexible photovoltaic apparatus of claim 2, wherein the thin film photovoltaic device is one selected from the group consisting of an amorphous silicon thin film photovoltaic device, a microcrystalline silicon thin film photovoltaic device, a CdS thin film photovoltaic device, a CdTe thin film photovoltaic device, a CuInSe₂ thin film photovoltaic device, a Cu(In,Ga)Se₂ thin film photovoltaic device and a dye-sensitized thin film photovoltaic device.

8. The flexible photovoltaic apparatus of claim 2, having a thickness in a range of about from 0.05 mm to 5 mm.

9. The flexible photovoltaic apparatus of claim 2, being capable of being wound into a tubular article, wherein a flexibility of said flexible photovoltaic apparatus is defined as a diameter of the tubular article which is about form 5 mm to 500 mm.

10. A flexible photovoltaic apparatus, comprising:
a fabric layer;
a first sealing layer, bonded on the fabric layer;
a thin film photovoltaic device, being bonded on the first sealing layer and having two terminals;
a second sealing layer, bonded on the thin film photovoltaic device; and
a protection layer, being transparent and being bonded on the second sealing layer, wherein said two terminals of the thin film photovoltaic device are exposed, and the fabric layer exhibits a decorative surface.

11. The flexible photovoltaic apparatus of claim 10, wherein the fabric layer is one selected from the group consisting of a textile layer, a natural leather layer and an artificial leather layer.

12. The flexible photovoltaic apparatus of claim 10, wherein the protection layer is formed of PTFE, PMMA, EVA and PET.

13. The flexible photovoltaic apparatus of claim 10, wherein the thin film photovoltaic device is one selected from the group consisting of an amorphous silicon thin film photovoltaic device, a microcrystalline silicon thin film photovoltaic device, a CdS thin film photovoltaic device, a CdTe thin film photovoltaic device, a CuInSe₂ thin film photovoltaic device, a Cu(In,Ga)Se₂ thin film photovoltaic device and a dye-sensitized thin film photovoltaic device.

14. The flexible photovoltaic apparatus of claim 10, having a thickness of in a range of about from 0.05 mm to 5 mm.

15. The flexible photovoltaic apparatus of claim 10, being capable of being wound into a tubular article, wherein a flexibility of said flexible photovoltaic apparatus is defined as a diameter of the tubular article which is about form 5 mm to 500 mm.

16. A flexible photovoltaic apparatus, comprising:
a fabric layer;
an interface layer, formed to overlay the fabric layer;
a first protection layer, bonded on the interface layer;
a first sealing layer, bonded on the first protection layer;
a thin film photovoltaic device, being bonded on the first sealing layer and having two terminals;
a second sealing layer, bonded on the thin film photovoltaic device; and
a second protection layer, being transparent and being bonded on the second sealing layer, wherein said two terminals of the thin film photovoltaic device are exposed, and the fabric layer exhibits a decorative surface.

17. The flexible photovoltaic apparatus of claim 16, wherein the fabric layer is one selected from the group consisting of a textile layer, a natural leather layer and an artificial leather layer.

18. The flexible photovoltaic apparatus of claim 16, wherein the first protection layer and the second protection layer are respectively formed of PTFE, PMMA, EVA and PET.

19. The flexible photovoltaic apparatus of claim 16, wherein the thin film photovoltaic device is one selected from the group consisting of an amorphous silicon thin film photovoltaic device, a microcrystalline silicon thin film photovoltaic device, a CdS thin film photovoltaic device, a CdTe thin film photovoltaic device, a CuInSe₂ thin film photovoltaic device, a Cu(In,Ga)Se₂ thin film photovoltaic device and a dye-sensitized thin film photovoltaic device.

20. The flexible photovoltaic apparatus of claim 16, having a thickness in a range of about from 0.05 mm to 5 mm.
